(19) United States
(12) Patent Application Publication
(10) Pub. No.: US 2016/0111257 A1
(43) Pub. Date: Apr. 21, 2016

(54) SUBSTRATE FOR MOUNTING GAS SUPPLY COMPONENTS AND METHODS THEREOF

(71) Applicant: Lam Research Corporation, Fremont, CA (US)

(72) Inventors: Michael C. Kellogg, Oakland, CA (US); Christopher J. Pena, Hayward, CA (US); John E. Daugherty, Fremont, CA (US)

(73) Assignee: Lam Research Corporation

(21) Appl. No.: 14/517,192

(22) Filed: Oct. 17, 2014

(51) Int. Cl. H01J 37/32; B32B 37/18; B32B 38/00; B32B 9/00; F17D 3/01; B32B 17/00; H01L 21/3065; H01L 21/67; F17D 1/02; F17D 3/16; B32B 3/10; B32B 15/04

(52) U.S. Cl. CPC H01J 37/3244; B32B 3/10; B32B 37/18; B32B 38/0004; B32B 9/005; B32B 15/04; B32B 17/00; H01L 21/3065; H01L 21/67069; F17D 1/02; F17D 3/16; F17D 3/01; B32B 2311/00; B32B 2315/08; B32B 2315/02

(57) ABSTRACT

A gas delivery substrate for mounting gas supply components of a gas delivery system for a semiconductor processing apparatus. The substrate includes a plurality of layers having major surfaces thereof bonded together forming a laminate with openings for receiving and mounting first, second, third and fourth gas supply components on an outer major surface. The substrate includes a first gas channel extending into an interior major surface that at least partially overlaps a second gas channel extending into a different interior major surface. The substrate includes a first gas conduit including the first gas channel connecting the first gas supply component to the second gas supply component, and a second gas conduit including the second channel connecting the third gas supply component to the forth gas supply component.

### FIELD OF THE INVENTION

The invention relates to gas delivery systems for semiconductor substrate processing apparatuses. More particularly, the invention relates to a gas delivery substrate for mounting gas supply components of a gas delivery system for a semiconductor processing apparatus.

### BACKGROUND

Semiconductor substrate processing apparatuses are used for processing semiconductor substrates by techniques including, but not limited to, plasma etching, physical vapor deposition (PVD), chemical vapor deposition (CVD), plasma enhanced chemical vapor deposition (PECVD), atomic layer deposition (ALD), plasma enhanced atomic layer deposition (PEALD), ion implantation, and resist removal. Semiconductor substrate processing apparatuses include gas delivery systems through which process gas is flowed and subsequently delivered into a processing region of a vacuum chamber of the apparatus by a gas distribution member such as a showerhead, gas injector, gas ring, or the like. For example, the gas delivery system can be configured to supply process gas to a gas injector positioned in the chamber above a semiconductor substrate so as to distribute process gas over a surface of the semiconductor substrate being processed in the chamber. Current gas delivery systems are constructed from many individual components, many of which have conduits therein through which process gas flows.

Conventional semiconductor processing systems typically utilize gas sticks. The term “gas sticks” refers, for example, to a series of gas distribution and control components such as a mass flow controller (MFC), one or more pressure transducers and/or regulators, a heater, one or more filters or purifiers, and shutoff valves. The components used in a given gas stick and their particular arrangement can vary depending upon their design and application. In a typical semiconductor processing arrangement, over seventeen gases may be connected to the chamber via gas supply lines, gas distribution components, and mixing manifolds. These are attached to a base plate forming a complete system known as a “gas panel” or “gas box” which serves as a mounting surface and does not play a role in gas distribution.

In general, a gas stick comprises multiple integrated surface mount components (e.g., valve, filter, etc.) that are connected to other gas control components through channels on a substrate assembly or base plate, upon which the gas control components are mounted. Each component of the gas stick is typically positioned above a manifold block in a linear arrangement. A plurality of manifold blocks form a modular substrate, a layer of manifold blocks that creates the flow path of gases through the gas stick. The modular aspect of conventional gas sticks allow for reconfiguration, much like children's LEGO® block toys. However, each component of a gas stick typically comprises highly machined parts, making each component relatively expensive to manufacture and replace. Each component is typically constructed with a mounting block, which in turn is made with multiple machine operations, making the component expensive. In addition, conventional gas sticks require a substantial amount of space, long connections between components, multiple seals between components, and comprise multiple potential failure points and contamination points. Also, the long connections result in gas delivery delays, which adversely affect gas pulsing times and switching times. Thus, there is a need for an improved substrate for mounting gas supply components for a semiconductor processing apparatus.

### SUMMARY

Disclosed herein is a gas delivery substrate for mounting gas supply components of a gas delivery system for a semiconductor processing apparatus. The substrate includes a plurality of layers having major surfaces thereof bonded together forming a laminate. The laminate includes openings configured to receive and mount at least a first gas supply component, a second gas supply component, a third gas supply component, and a fourth gas supply component on an outer major surface of at least one of the layers. The substrate includes a first gas channel extending at least partially into an interior major surface of one of the layers, a second gas channel extending at least partially into a different interior major surface of one of the layers, wherein the first gas channel is at least partially overlapping the second gas channel. In addition, the substrate includes a first gas conduit including the first gas channel configured to connect the first gas supply component to the second gas supply component, and a second gas conduit including the second channel configured to connect the third gas supply component to the forth gas supply component.

Also disclosed herein is a system for a gas block that includes the gas delivery substrate. The system includes gas supply components mounted on at least one major surface. In one embodiment, the gas supply components can be mounted on opposed major surfaces. In another embodiment, the system includes an on/off gas valve connected to an MFC through a gas conduit within the substrate, another on/off gas valve connected to a mixing manifold through a gas conduit within the substrate, and a mixing manifold exit connected to one or more openings on the laminate.

Disclosed herein is a method of producing the gas delivery substrate. The method includes creating a first gas channel extending into an interior major surface of at least one layer of a plurality of layers having major surfaces thereof, creating a second gas channel extending at least partially into a different interior major surface, and creating openings on an outer major surface. At least some of the openings are mounting holes configured to receive and mount at least a first gas supply component, a second gas supply component, a third gas supply component, and a fourth gas supply component. The method further includes bonding the layers together to form a laminate such that the first gas channel is at least partially overlapping the second gas channel, the first gas channel forms part of a first gas conduit connecting the first gas supply component to the second gas supply component, and the second gas channel forms part of a second gas conduit connecting the third gas supply component to the fourth gas supply component.

Disclosed herein is a method of delivering gas through the gas delivery substrate, wherein gases are supplied through the openings of the laminate. The method includes delivering a first gas from the first gas supply component to the second gas supply component through the first gas channel, and delivering the first gas from the second gas supply component to a mixing manifold within the substrate through a third gas channel in the substrate. The method further includes delivering a second gas from the third gas supply component to the fourth gas supply component through the second gas channel, and delivering the second gas from the fourth gas supply component to the mixing manifold within the substrate through a fourth gas channel in the substrate. The method includes mixing the first gas and the second gas in the mixing manifold to create a first gas mixture and delivering the first gas mixture through one or more gas channels in the substrate and/or one or more outlets on the substrate to a semiconductor processing chamber downstream.

### BRIEF DESCRIPTION OF THE DRAWING FIGURES

FIG. 1 illustrates an embodiment of a semiconductor substrate processing apparatus in accordance with embodiments disclosed herein.

FIG. 2 is a schematic of a gas delivery system, in accordance with embodiments disclosed herein.

FIG. 3 illustrates an example of a gas stick.

FIG. 4 illustrates an embodiment of a single layer in a gas delivery substrate for mounting gas supply components of a gas delivery system for a semiconductor processing apparatus, in accordance with embodiments disclosed herein.

FIG. 5A illustrates multiple layers in a gas delivery substrate for mounting gas supply components before being bonded together, in accordance with embodiments disclosed herein.

FIG. 5B illustrates multiple layers in a gas delivery substrate for mounting gas supply components of a gas delivery system after being bonded together, in accordance with embodiments disclosed herein.

FIG. 6A illustrates an embodiment of a gas delivery substrate for mounting gas supply components of a gas delivery system for a semiconductor processing apparatus, in accordance with embodiments disclosed herein.

FIG. 6B illustrates a detailed view of a cross section of the gas delivery substrate shown in FIG. 6A.

FIG. 7A illustrates an embodiment of a gas delivery substrate for mounting gas supply components of a gas delivery system for a semiconductor processing apparatus, in accordance with embodiments disclosed herein.

FIG. 7B illustrates a top view of the gas delivery substrate shown in FIG. 7A.

### DETAILED DESCRIPTION

Disclosed herein is a gas delivery substrate for mounting gas supply components of a gas delivery system for a semiconductor processing apparatus and methods for producing and using the same. The semiconductor substrate processing apparatus can be used for processing semiconductor substrates by techniques including, but not limited to, plasma etching, physical vapor deposition (PVD), chemical vapor deposition (CVD), plasma enhanced chemical vapor deposition (PECVD), atomic layer deposition (ALD), plasma enhanced atomic layer deposition (PEALD), ion implantation, or resist removal. In the following description, numerous specific details are set forth in order to provide a thorough understanding of the present embodiments. It will be apparent, however, to one skilled in the art that the present embodiments may be practiced without some or all of these specific details. In other instances, well known process operations have not been described in detail in order not to unnecessarily obscure present embodiments disclosed herein. Additionally, as used herein, the term “about” when used with reference to numerical values refers to ±10%.

As integrated circuit devices continue to shrink in both their physical size and their operating voltages, their associated manufacturing yields become more susceptible to contamination. Consequently, fabricating integrated circuit devices having smaller physical sizes requires that the level of contamination be less than previously considered to be acceptable. In addition, the wafers and processing equipment used in semiconductor processing are becoming more complex and larger in size, in order to produce more dies per wafer. Accordingly, producing and maintaining the equipment and manufacturing the wafers is becoming more expensive.

Gas distribution systems of semiconductor substrate processing apparatuses can utilize gas sticks which are a series of gas distribution and control components such as a mass flow controller (MFC), one or more pressure transducers and/or regulators, one or more heaters, one or more filters or purifiers, manifolds, gas flow adaptors, and shutoff valves. The components used and their particular arrangement in a gas stick can vary depending upon their design and application. For example, in a semiconductor substrate processing arrangement, over seventeen process gases can be supplied to the chamber via gas supply lines and gas distribution system components. The gas distribution system components are attached to a base plate (i.e. gas pallet) forming the system which is also known as a “gas panel” or “gas box.”

As discussed above, gas delivery system components are made from metals such as stainless steel or other metal alloys wherein constituent components are assembled together, requiring interfaces and seals between the constituent components, in order to achieve a desired conduit path for process gas. However, the constituent components typically comprise highly machined parts, making each component relatively expensive to manufacture, maintain and replace. Each component is typically constructed with a mounting block, which in turn is made with multiple machine operations, making the component expensive. Interchangeable components require a substantial amount of space and longer connections to connect the components with each other. Thus, the interchangeable components have multiple potential failure points, contamination points, and introduce gas delivery delays.

Corrosion, erosion, and/or corrosion/erosion in environments, such as those formed in the interior of gas delivery systems may contain oxygen, halogens, carbonyls, reducing agents, etching gases, depositing gases, and/or hydro-fluorocarbon process gas, or process gases which may be used in semiconductor substrate processing such as but not limited Cl₂, HCl, BCl₃, Br₂, HBr, O₂, SO₂, CF₄, CH₂F₂, NF₃, CH₃F, CHF₃, SF₆, CO, COS, SiH₄ H₂. In addition inert gases, such as but not limited Ar and N₂, may be supplied to said environments.

Accordingly, disclosed herein is a gas delivery substrate for mounting gas supply components of a gas delivery system for a semiconductor processing apparatus and methods for producing and using the same. The substrate can be formed from laminated layers which are bonded together to create a uniform monolithic structure having gas tight channels that can be in fluid communication with each other. The substrate can be configured to receive and mount gas supply components such that the gas supply components are in fluid communication with each other via channels within the substrate. The layered structure of the substrate can allow channels or connections to be created of any size, in any direction, in three dimensional space (e.g., X-direction, Y-direction, and Z-direction) within the substrate. In this way, gas supply components of a gas delivery system can be housed closer together and the connections between components can be made shorter, which reduces the size of the gas delivery system. In addition, gas supply components and their connections often need to be made from high quality materials, such as expensive metal alloys (e.g., Hastelloy®), glass or ceramics. In an embodiment, all of the metallic surfaces which may contact process gases (i.e. become chemically wetted) can be eliminated or reduced so as to comply with on wafer (i.e. substrate) purity requirements. This compact design allows for reduced material costs while also reducing the number of possible contamination and failure points, and faster gas delivery pulsing and switching times for a gas delivery system.

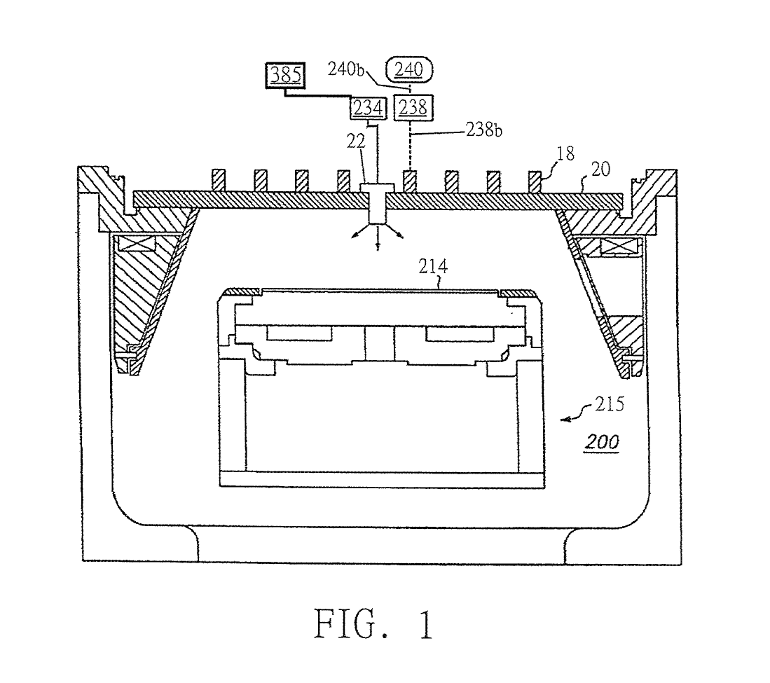

FIG. 1 illustrates an embodiment of a semiconductor substrate processing apparatus which can include a gas delivery system 234 including a gas delivery substrate for mounting gas supply components, as disclosed herein. As shown in FIG. 1, an inductively coupled plasma processing apparatus can include a vacuum chamber 200 (i.e. plasma etch chamber). The vacuum chamber 200 includes a substrate support (lower electrode assembly) 215 for supporting a semiconductor substrate 214 in the interior of the vacuum chamber 200. A dielectric window 20 forms a top wall of vacuum chamber 200. Process gases are injected to the interior of the vacuum chamber 200 through a gas injector 22. The gas delivery system 234 supplies process gases to the interior of the vacuum chamber 200 through gas injector 22. Parameters (e.g., temperature, flow rate, and chemical makeup) of the process gases supplied to the interior of the vacuum chamber by the gas delivery system are preferably controlled by a control system 385.

Once process gases are introduced into the interior of vacuum chamber 200, they are energized into a plasma state by an antenna 18 supplying energy into the interior of vacuum chamber 200. Preferably, the antenna 18 is an external planar antenna powered by a RF power source 240 and RF impedance matching circuitry 238 to inductively couple RF energy into vacuum chamber 200. However, in an alternate embodiment, the antenna 18 may be an external or embedded antenna which is nonplanar. An electromagnetic field generated by the application of RF power to the antenna energizes the process gas in the interior of the vacuum chamber 200 to form high-density plasma (e.g., 10⁹-10¹² ions/cm³) above substrate 214. During an etching process, the antenna 18 (i.e. a RF coil) performs a function analogous to that of a primary coil in a transformer, while the plasma generated in the vacuum chamber 200 performs a function analogous to that of a secondary coil in the transformer. Preferably, the antenna 18 is electrically connected to the RF impedance matching circuitry 238 by an electrical connector 238b (i.e. lead) and the RF power source 240 is electrically connected to the RF impedance matching circuitry 238 by an electrical connector 240b.

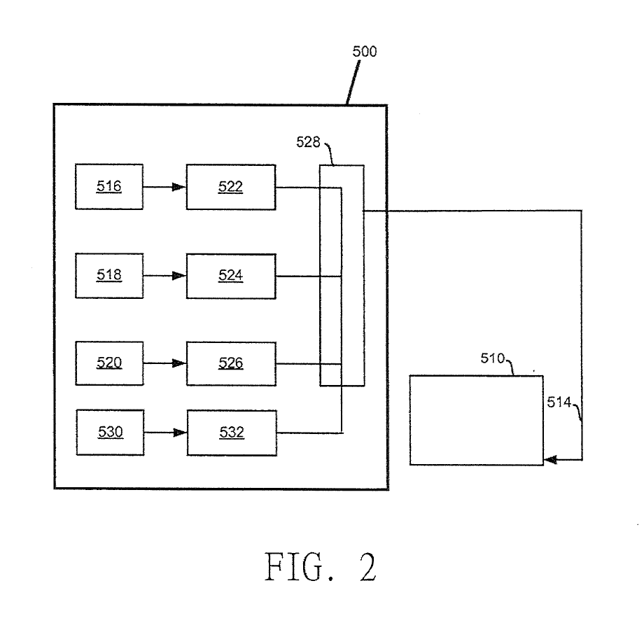

FIG. 2 is a schematic view of an exemplary gas delivery system 500 for a semiconductor substrate processing apparatus processing including a gas delivery substrate for mounting gas supply components, as disclosed herein. A vacuum chamber 510 of a semiconductor substrate processing apparatus is supplied process gas through a gas supply line 514. The gas supply line 514 can provide process gases, such as etching and deposition gases which may be alternatively supplied or pulsed, to a gas distribution member such as a showerhead or a gas injector arranged in the upper portion of the vacuum chamber 510, and downstream of the gas delivery system 500. Additionally, gas supply line 514 may supply process gas to a lower portion of the vacuum chamber such as, for example, to a gas distribution ring surrounding the semiconductor substrate support or through gas outlets arranged in the substrate support. Processing gas may be supplied to gas line 514 from gas supplies 516, 518, 520, 530 with the process gases from supplies 516, 518, 520, 530 being supplied to MFCs 522, 524, 526, 532 respectively. The MFCs 522, 524, 526, 532 supply the process gases to a mixing manifold 528 after which the mixed gas is directed to gas flow line 514. Mixing manifold 528 may be within a substrate for mounting gas supply components or external to the substrate. The gas delivery system 500 includes a substrate for mounting gas supply components, as disclosed herein.

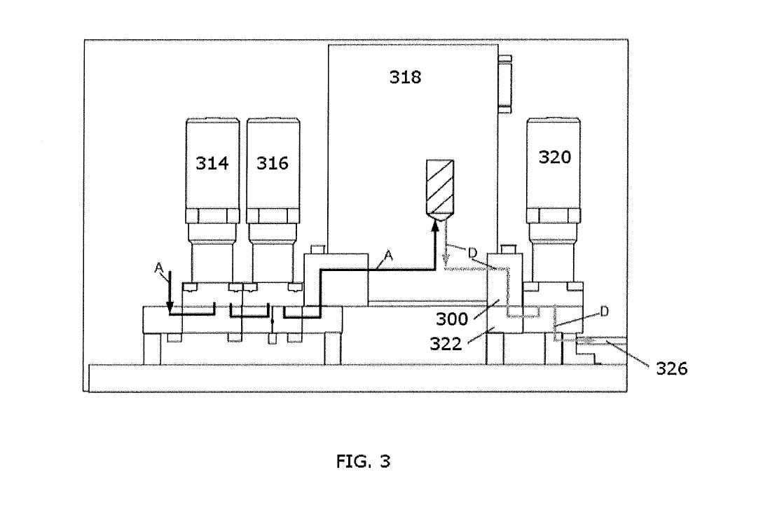

FIG. 3 illustrates a cross section of a prior art gas stick with a modular substrate 322 and the flow of gases through the gas stick. The gas may flow through primary shut-off valve 314, out of the purge valve 316 and into MFC 318 in the direction of flow path A. The gas may then flow out of the MFC 318 into the substrate 322, through the mixing valve 320 and into a mixing manifold (not shown), as illustrated by flow path D.

Substrate 322 is of a modular design which comprises multiple interchangeable parts which are connected to each other with seals, which introduce potential failure points. Since substrate 332 is made up of multiple parts, it allows for a LEGO® type construction. However, this design causes the flow path between gas supply components to become long, which increases size, introduces multiple failure points and delays when delivering gas.

Accordingly, disclosed herein is a gas delivery substrate for mounting gas supply components of a gas delivery system that can be formed from stacked layers which are bonded together to create a uniform monolithic structure that is configured to receive and mount gas supply components such that the gas supply components are in fluid communication with each other via channels within the substrate. The layered structure of the substrate can allow gas channels or conduits to be created of any size, in any direction. In addition, the layered substrate can include channels or conduits for running electrical wire connections between gas supply comments. Also, the substrate can include channels or conduits for carrying air between gas supply components. For example, the channels or conduits within the substrate can provide air supply connections between a pneumatic manifold and diaphragm values (e.g., on/off valves). For example, the diaphragm valves can include a solenoid which is actuated by air, in order to control the flow of gas. Thus, gas supply components can be housed closer together on the substrate and the connections between components can made shorter than the connections within substrate 322, as shown in FIG. 3.

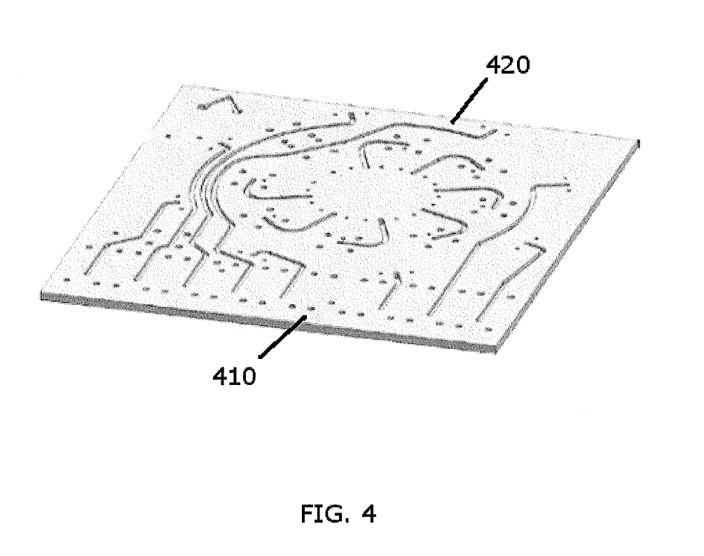

FIG. 4 illustrates an embodiment of a gas delivery substrate for mounting gas supply components of a gas delivery system for a semiconductor processing apparatus, as disclosed herein. FIG. 4 shows an example of a single layer which can be included in a substrate comprising stacked layers that are bonded together. The layers of the substrate can be made from any suitable material, such as ceramic, metal, metal alloy, glass or composites. A layer of the substrate can also include one or more chambers or plenums. Alternatively, the substrate may include one or more chambers or plenums which extend through two or more layers of the substrate which can form part of a mixing manifold. The substrate may include one or more heaters for heating processing gases. In addition, the substrate can incorporate one or more flow restrictors (e.g., a filter with one or more small openings) across one or more layers of the substrate. In addition, a flow splitter can be created within one or more layers of the substrate for diverting gas.

As shown in FIG. 4, a layer can include multiple vertical through holes 410 and horizontal channels 420. Vertical through holes 410 can be configured as gas conduits to provide fluid communication and/or fasten to attach gas supply components to the substrate. The vertical through holes 410 used for gas conduits can be coated with one or more additional materials, such as metal, glass, plastic, ceramic, metal alloys, or composites.

In addition, vertical through holes 410 can take any shape, pattern or direction. Vertical through holes 410 can extend partially and/or completely through a layer. Also, vertical through holes 410 can be configured to create a gas tight connection with vertical through holes and/or horizontal channels of another layer when multiple layers are bonded together. Vertical through holes 410 can be set perpendicular to a plane of a layer or at any angle which respect to the plane of the layer. Vertical through holes 410 can be tapered in size. For example, vertical through holes 410 can be wider at one end and smaller at another end. In other words, vertical through holes 410 can extend vertically or at an angle in any direction within the three dimensional space of a layer (e.g., X-direction, Y-direction, and Z-direction).

Also shown in FIG. 4, a layer of the gas delivery substrate can include horizontal channels 420. Horizontal channels 420 can be linear or take any shape, pattern or direction. Horizontal channels 420 can extend partially into or completely through the layer. Also, horizontal channels 420 can be formed at different angles which respect to a plane of the layer. For example, the horizontal channels 420 can have a slope that is higher at one end and lower at another end. The slope of a channel can also be varied (e.g., zigzag, curving or undulating). In addition, horizontal channels 420 can be configured to create a gas tight connection with vertical through holes 410 and/or horizontal channels 420 of another layer when the layers are bonded together to form a gas conduit. Alternatively, vertical through holes 410 can connect to horizontal channels 420 within the same layer to form a gas conduit. Horizontal channels 420 can be set parallel to a plane of the layer or at any angle with respect to the plane of the layer. Interior surfaces of horizontal channels 420 and vertical through holes 410 can be coated with corrosion resistant material, such as siloxane, see U.S. Patent Application Publication No. 2011/0259519, the disclosure of which is hereby incorporated. Some horizontal channels can partially or fully overlap other horizontal channels. Also, some horizontal channels can crisscross other horizontal channels and/or some vertical channels. In this way, connections between gas supply components can be more efficiently routed, in order to save space and reduce the overall footprint of the substrate.

In addition, horizontal channels 420 can follow any path (e.g., winding or curved) within a layer. Horizontal channels 420 can extend in any direction within the layer. For example, horizontal channels 420 can extend radially from a common point or curve around a common point in the axial direction. In other words, horizontal channels 420 can extend any in direction in the three dimensional space of a layer (e.g., X-direction, Y-direction, and Z-direction). In addition, horizontal channels 420 can extend partially into an interior major surface of a layer or completely through an interior major surface of a layer within the substrate.

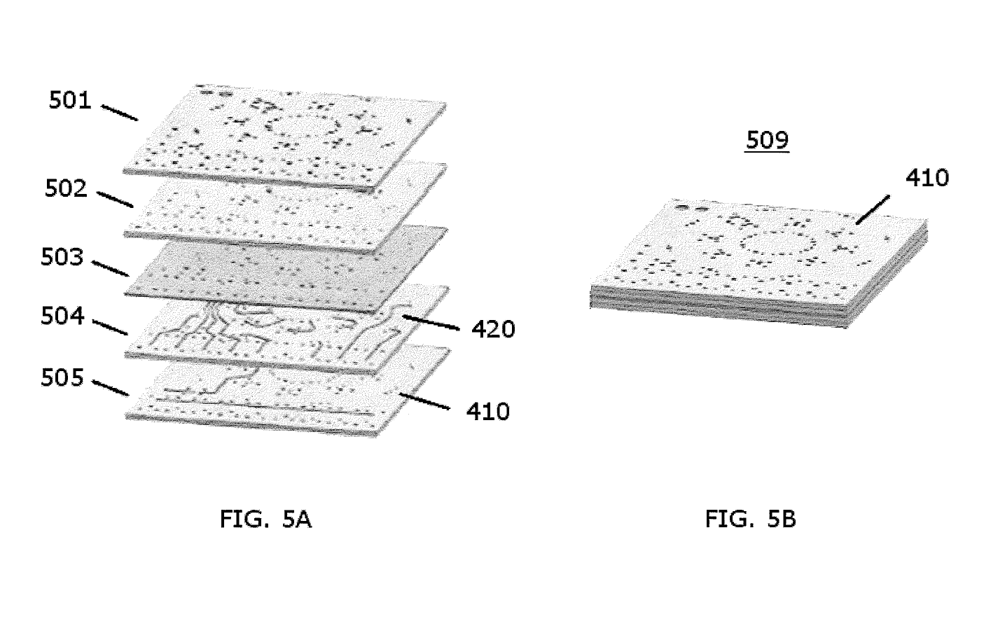

Referring now to FIG. 5A and FIG. 5B, embodiments of a gas delivery substrate for mounting gas supply components of a gas delivery system are shown comprising multiple layers 501-505. FIG. 5A shows different layers 501-505 of a substrate before being bonded together. For example, the gas delivery substrate can include a first layer 501 including vertical through holes and a second layer 502 having vertical through holes and horizontal gas channels. In addition, the substrate can include a third layer 503, a fourth layer 504 and a fifth layer 505. Each layer of the substrate can have vertical through holes and/or horizontal channels, some of which are gas conduits. The horizontal gas channels in one layer can partially overlap or fully overlap horizontal gas channels in other layers. Also, each layer may include one or more chambers or plenums, which may extend partially through a layer or completely through one or more layers. A chamber or plenum can form part of a mixing manifold. Each layer can comprise vertical through holes, horizontal channels, chambers and/or plenums. The layers can be bonded together through firing, sintering, adhesive, friction, pressure, welding, soldering, cold spraying and heat treatment, ultrasonic welding, cooling, brazing or diffusion bonding. By selecting a proper material for each layer and the bonding material the substrate can improve corrosion resistance and gas purity while also reducing cost by avoiding expensive metal alloys (e.g., Hastelloy®, or stainless steel e.g., 316). Alternatively, the layers can be bonded together through any mechanical means, such as clamps, bolts, screws, rivets, or through bolts.

FIG. 5B illustrates a gas delivery substrate comprising multiple layers bonded together to form a monolith structure 509. While five layers are shown for the substrate in FIG. 5A and FIG. 5B, any number layers can be used to form the substrate. The layers of the substrate can be made of the same material such that when bonded together form a uniform monolith structure. Each layer of the substrate can have a uniform thickness or a non-uniform thickness. Alternatively, different materials can be used for each layer. For example, the outer layers can be formed from a higher quality material than the inner layers and vice versa. In addition, the layers can have identical shapes or different shapes or configurations. For example, two layers can be spaced apart and reside on top of the same layer. In another example, one layer may have a rectangular shape while another layer may have a circular shape.

Also shown in FIG. 5A and FIG. 5B are vertical through holes 410 on the substrate for mounting gas supply components, some of which are openings for gas passages. The vertical through holes 410 can also be used for mounting the substrate or fastening the layers together. The layers can be bonded together to form a monolithic structure configured to receive and mount gas supply components.

The substrate can be formed such that it is configured to receive and mount gas supply components on both the top layer and bottom layer. In addition, the substrate can be formed with three sides or more sides (e.g., a triangular shape, a rectangle, pentagon, hexagon, etc.), such that the one or more sides of the substrate are configured to receive and mount gas supply components. Alternatively, the layered substrate can be formed in a circular, oval or curvy shape (e.g., a single vertical side). Also, the substrate can be formed with a mixture of flat angular sides and curved sides (e.g., a “D” shape). In addition, the substrate can be formed such that it is configured with one or more gas inlets and one or more gas outlets. The gas inlets and outlets can be included in any layer or across more than one layer of the substrate. The gas outlets can be configured to connect to one or more gas lines and/or a processing chamber downstream.

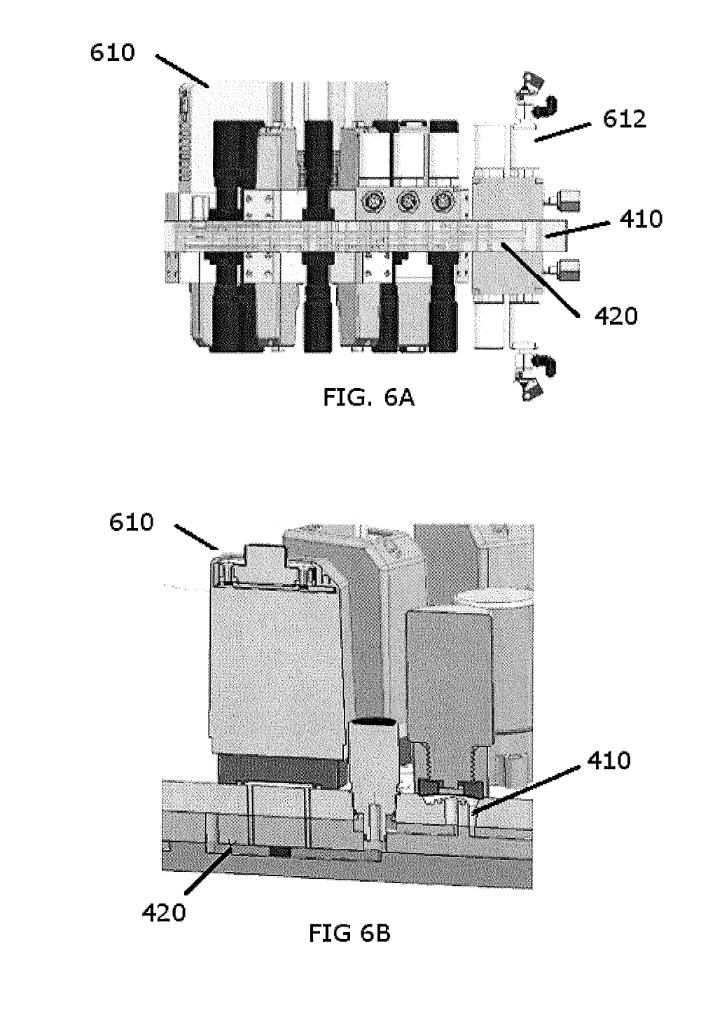

FIG. 6A and FIG. 6B illustrate two views of an embodiment of a gas delivery substrate for mounting gas supply components of a gas delivery system for a semiconductor processing apparatus as disclosed herein. FIG. 6A shows a side view of a gas delivery substrate with gas supply components 610 and 612 mounted on both the top layer and bottom layer of the substrate. FIG. 6B illustrates a close up view of a cross section of the substrate shown in FIG. 6A. As shown in FIG. 6B, gas supply components 610 can be in fluid communication with each other via vertical through holes 410 and horizontal channels 420 within different layers of the substrate. The different layers of the substrate can be bonded together such that the vertical through holes 410 and horizontal channels 420 within the layers form gas tight connections or paths through the substrate.

As shown in FIG. 6B, vertical through holes 410 and horizontal channels 420 of different layers of the substrate can connect to form gas tight channels between gas supply components 610. The gas supply components 610 can be mounted on any side of the substrate. Vertical through holes 410 and horizontal channels 420 within different layers of the substrate can connect gas supply components that are mounted on different sides of the substrate. For example, vertical through holes 410 and horizontal channels 420 of different layers can connect to place a gas supply component mounted on a top layer in fluid communication with a gas supply component mounted on a bottom layer. In other words, the substrate comprises an interleaved mesh interconnect of different conduits and channels which can connect to various gas supply components. In addition to housing conduits within the layers of the substrate, one or more layers of the substrate may include a gas flow splitter, a heater, a restrictor (e.g., a filter with one or more small holes), and/or a gas mixing manifold. In an embodiment, the layers of the substrate can include air conduits. For example, the air conduits can allow a pneumatic manifold to connect to and control diaphragm valves or air actuators mounted on the substrate.

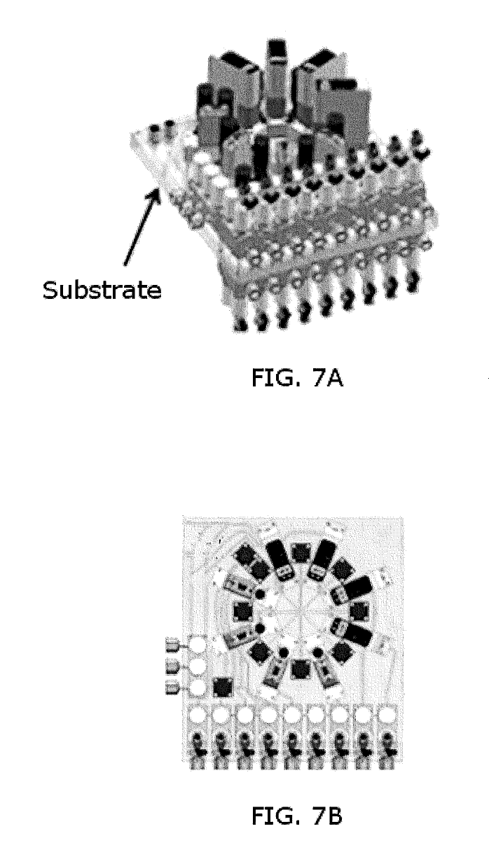

Referring now to FIG. 7A and FIG. 7B, an embodiment of a gas delivery substrate for mounting gas supply components of a gas delivery system for a semiconductor processing apparatus is illustrated. For example, FIG. 7A and FIG. 7B show alternate views of the substrate mounted with gas supply components depicted in FIG. 6A. FIG. 7A shows a three-dimensional view of the substrate with gas supply components mounted on both sides. FIG. 7B illustrates a top view of the substrate shown in FIG. 7A. The substrate can be configured to receive and mount gas supply components in any configuration. For example, the gas supply components can be organized in different sections on any side of the substrate. In addition, the substrate can be configured with one or more gas outlets or openings for allowing gas to exit the substrate. The outlets can be included on any side of the substrate. The gas outlets can be configured to connect to one or more gas lines and/or a processing chamber downstream.

The gas delivery substrate can be configured to receive and mount gas supply components such that different components can be shared between different gas lines. This design can save space and reduce costs while also reducing gas pulsing and switching times. In addition, FIG. 7B illustrates an example of the substrate being configured to receive and mount gas supply components in a circumferentially spaced arrangement on the substrate. In other words, the gas supply components can be spaced in a ring formation around a common point. For example, the substrate can comprise a multi-inlet mixing manifold, where the gas inlets are spaced equally from a center mixing chamber of the manifold. In such an arrangement, the length scales for all gas species approach zero, or are zero. The gas inlets can be spaced on the substrate such that radial lines drawn from the gas inlets to a center point of the center mixing chamber or plenum are the same length.

For example, a mixing manifold within the substrate can include a cylindrical mixing chamber housed within one or more layers or on a surface of the substrate, and the gas inlets may be located at circumferentially spaced locations on any side of the substrate. Arranging all gases in a cylindrical arrangement in this way collapses a linear tubular design into a single mixing point—that is to say, by arranging all gases in a circular arrangement such that the length scale approaches zero (or is zero), high and low flow gases can be mixed instantly, and co-flow effects (i.e., gas mixing delays due to gas position or location) can be eliminated.

In embodiments, a manual valve may be mounted on the gas delivery substrate for carrying out the supply or isolation of a particular gas supply. The manual valve may also have a lockout/tagout device above it. Worker safety regulations often mandate that plasma processing manufacturing equipment include activation prevention capability, such as a lockout/tagout mechanism. A lockout generally refers, for example, to a device that uses positive means such as a lock, either key or combination type, to hold an energy-isolating device in a safe position. A tagout device generally refers, for example, to any prominent warning device, such as a tag and a means of attachment that can be securely fastened to an energy-isolating device in accordance with an established procedure.

A regulator may be mounted on the gas delivery substrate to regulate the gas pressure of the gas supply and a pressure gas may be used to monitor the pressure of the gas supply. In embodiments, the pressure may be preset and need not be regulated. In other embodiments, a pressure transducer having a display to display the pressure may be used. The pressure transducer may be positioned next to the regulator. A filter may be used to remove impurities in the supply gas. A primary shut-off valve may be used to prevent any corrosive supply gases from remaining in the substrate. The primary shut-off valve may be, for example, a two-port valve having an automatic pneumatically operated valve assembly that causes the valve to become deactivated (closed), which in turn effectively stops gas flow within the substrate. Once deactivated, a non-corrosive purge gas, such as nitrogen, may be used to purge one or more portions within the substrate. The purge gas component and the substrate may have, for example, three ports to provide for the purge process (i.e., an entrance port, an exit port, and a discharge port).

A mass flow controller (MFC) may be located adjacent the purge valve. The MFC accurately measures the flow rate of the supply gas. Positioning the purge valve next to the MFC allows a user to purge any corrosive supply gases in the MFC. A mixing valve next to the MFC may be used to control the amount of supply gas to be mixed with other supply cases on the substrate. In an embodiment, a portion of the MFC can be built into one or more layers of the substrate. For example, a flow restrictor (e.g., a filter with one or more small holes) or a flow diverter can be built into one or more layers of the substrate.

In embodiments, a discrete MFC may independently control each gas supply. Exemplary gas component arrangements, and methods and apparatuses for gas delivery are described, for example, in U.S. Patent Application Publication No. 2010/0326554, U.S. Patent Application Publication No. 2011/0005601, U.S. Patent Application Publication No. 2013/0255781, U.S. Patent Application Publication No. 2013/0255782, U.S. Patent Application Publication No. 2013/0255883, U.S. Pat. No. 7,234,222, U.S. Pat. No. 8,340,827, and U.S. Pat. No. 8,521,461, each of which are commonly assigned, and the entire disclosures of which are hereby incorporated by reference herein in their entireties.

In other embodiments, MFCs may be used to initiate the desired flow set point for each gas and then release the respective gases for immediate mixing in a mixing manifold within the gas delivery substrate. Individual gas flow measurement and control may be performed by each respective MFC. Alternatively, a single MFC controller can operate multiple gas lines.

In embodiments, MFCs may be controlled by a remote server or controller. Each of the MFCs may be a wide range MFC having the ability to perform as either a high flow MFC or a low flow MFC. The controller may be configured to control and change the flow rate of a gas in each of the MFCs.

The present disclosure further provides, in embodiments, a method of using a gas delivery substrate for mounting gas supply components of a gas delivery system for a semiconductor processing apparatus for supplying process gas to a processing chamber of a plasma processing apparatus. Such a method may include, for example, delivering different gases between gas supply components mounted on the substrate through conduits within the substrate to a mixing manifold or chamber within the substrate. Initially, the gases are delivered to the substrate through a plurality of gas inlets on a surface thereof. After mixing within a mixing manifold, the gases exit the substrate through one or more outlets. The gas inlets can be equally spaced from a center mixing chamber of the mixing manifold, such that the length scale of each gas species is the same and when gas is flowed from gas supplies to the mixing manifold within the substrate, the gas delivery time for each gas is the same. Alternatively, the gas supply components and gas inlets can be spaced in linear or non-linear arrangements.

Such a method may further include, for example, delivering gas through a gas delivery substrate including a first layer having vertical through holes, a second layer having vertical through holes and horizontal gas channels, and a third layer having vertical through holes, some of which are gas conduits. The first, second and the third layers of the substrate being bonded together such that the horizontal gas channels of the second layer are in fluid communication with at least some of the vertical through holes in the first layer and/or the third layer. The method further includes delivering the gas between a plurality of gas supply components via the second layer and the first layer and/or the third layer of the substrate. In addition, the gas delivery substrate includes one or more openings for allowing gas to exit the substrate to one or more gas lines or to a downstream processing chamber.

In addition, the present disclosure provides a method of supplying process gas through a gas delivery substrate for mounting gas supply components to a processing chamber of a plasma processing apparatus. Such a method may include, for example, delivery gases from a plurality of gas supplies in fluid communication with a plurality of gas inlets on a surface of a substrate for mounting gas supply components having at least one mixing manifold outlet; flowing at least two different gases from the plurality of gas supplies to the substrate to create a gas mixture; and supplying the gas mixture to a plasma processing chamber coupled downstream of the substrate. In an embodiment, the gas mixture can be combined with a tuning gas before delivery to a processing chamber downstream.

In embodiments, mass flow controllers can initiate flow set points for each of the at least two different gases and release them simultaneously for immediate mixing in a mixing manifold within the substrate. One of the gases may be a tuning gas which may be delivered to the mixing manifold of combined to the gas mixture downstream from a mixing manifold.

In an embodiment, gas enters the substrate via a plurality of gas inlets/openings on a surface of the substrate and enters a mixing manifold within the substrate. The gas mixture may then exit the substrate via one or more exit outlets/openings. After exiting the substrate, the gas may be delivered to one or more gas lines, or directly to a processing chamber. The mixing manifold may be provided within one or more layers of the substrate or be external to the substrate. In other embodiments, the gas may be added to another array of gases or mixed gases, another substrate mounted with gas supply components or a gas stick.

While embodiments disclosed herein have been described in detail with reference to specific embodiments thereof, it will be apparent to those skilled in the art that various changes and modifications can be made, and equivalents employed, without departing from the scope of the appended claims.

What is claimed is:

1. A gas delivery substrate for mounting gas supply components of a gas delivery system for a semiconductor processing apparatus, the substrate comprising:
a plurality of layers having major surfaces thereof bonded together forming a laminate, wherein the laminate includes openings, at least some of which are mounting holes, configured to receive and mount at least a first gas supply component, a second gas supply component, a third gas supply component, and a fourth gas supply component on an outer major surface;
a first gas channel extending at least partially into an interior major surface;
a second gas channel extending at least partially into a different interior major surface, wherein the first gas channel is at least partially overlapping the second gas channel;
a first gas conduit including the first gas channel configured to connect the first gas supply component to the second gas supply component; and
a second gas conduit including the second gas channel configured to connect the third gas supply component to the forth gas supply component.

2. The substrate of claim 1, wherein the laminate includes:
a plurality of inner layers, wherein the inner layers include horizontal gas channels and/or vertical through holes, wherein the horizontal gas channels and/or vertical through holes form part of the first gas conduit or the second gas conduit; and
at least two outer layers, wherein at least one of the outer layers includes mounting holes configured to receive fasteners to mount the gas supply components on the laminate, and openings which form part of the first gas conduit or the second gas conduit.

3. The substrate of claim 2, wherein at least one of the inner layers includes a plenum in fluid communication with at least one of the openings, a plurality of horizontal gas channels radially extending from a common point, one or more heaters for heating gas, a gas flow splitter, a filter forming a gas restrictor, and/or a non-linear gas channel.

4. The substrate of claim 2, wherein at least one of the horizontal gas channels or vertical through holes forms an angle with respect to a plane of a layer.

5. The substrate of claim 2, wherein the inner layers include horizontal gas channels and vertical through holes in fluid communication with the openings of the outer layers.

6. The substrate of claim 5, wherein the inner layers include a plenum extending through more than one inner layer that is in fluid communication with at least some of the openings of the outer layers.

7. The substrate of claim 5, further comprising:
an inner layer, residing between at least two other inner layers, including vertical holes and/or horizontal gas channels, wherein at least some of the vertical holes and/or horizontal gas channels are in fluid communication with at least some of the openings of the outer layers.

8. The substrate of claim 7, wherein the inner layer, residing between the at least two other inner layers, includes a plenum in fluid communication with at least some of the openings of the outer layers.

9. The substrate of claim 1, wherein the layers are bonded through firing, sintering, adhesive, welding, soldering, cold spraying and heat treatment, ultrasonic welding, brazing, diffusion bonding, clamps, bolts, screws, or rivets.

10. The substrate of claim 1, wherein the layers are made from the same or different material selected from ceramic, glass, metal or a polymer.

11. The substrate of claim 1, wherein the outer layers include a plurality of gas inlets and one or more gas outlets.

12. The substrate of claim 1, wherein the laminate includes air conduits extending through one or more layers configured to carry air between a pneumatic manifold and diaphragm valves and/or wire conduits extending through one or more layers configured route wires to or from gas supply components.

13. A system for a gas block including the substrate of claim 1, the system including a plurality of gas supply components mounted on at least one outer major surface,
wherein the mounted gas supply components are selected from a group comprising: an on/off gas valve, a mass flow controller (MFC), a vacuum coupling radiation (VCR) fitting, a manual gas valve, a gas pressure regulator, a gas filter, a purge gas component, a gas flow restrictor, and a pressure transducer.

14. The system of claim 13, wherein the plurality of gas supply components are mounted on at opposed outer major surfaces.

15. The system of claim 13, further including:
a first on/off gas valve connected to an MFC through a gas conduit within the substrate;
a second on/off gas valve connected to the MFC through a gas conduit within the substrate, wherein the second on/off gas valve is connected to a mixing manifold through a gas conduit within the substrate; and
a mixing manifold exit connected to one or more of the openings on the laminate.

16. The system of claim 15, wherein: (a) some of the gas conduits crisscross each other, and at least some of the mounted gas supply components are arranged on one or two outer major surfaces in a non-linear arrangement, or (b) some of the gas conduits crisscross each other, and at least some of the mounted gas supply components are arranged on one or two outer major surfaces in a circular arrangement.

17. The system of claim 15, wherein gas paths between gas inlets on the laminate to a mixing manifold in the laminate has equal lengths.

18. A method of producing the gas delivery substrate of claim 1, said method comprising:
creating a first gas channel extending at least partially into an interior major surface of at least one layer of a plurality of layers having major surfaces thereof;
creating a second gas channel extending at least partially into a different interior major surface;
creating openings on an outer major surface at least some of which are mounting holes configured to receive and mount at least a first gas supply component, a second gas supply component, a third gas supply component, and a fourth gas supply component; and
bonding the plurality of layers together to form a laminate such that the first gas channel is at least partially overlapping the second gas channel, the first gas channel forms part of a first gas conduit configured to connect the first gas supply component to the second gas supply component, and the second gas channel forms part of a second gas conduit configured to connect the third gas supply component to the fourth gas supply component.

19. A method of delivering gas through the substrate of claim 1, wherein a plurality of gases are supplied through the openings of the laminate, wherein the plurality of gases include at least a first gas and a second gas;
delivering the first gas from the first gas supply component to the second gas supply component through the first gas channel;
delivering the second gas from the third gas supply component to the fourth gas supply component through the second gas channel;
delivering the first gas from the second gas supply component to a mixing manifold within the substrate through a third gas channel in the substrate;
delivering the second gas from the fourth gas supply component to the mixing manifold within the substrate through a fourth gas channel in the substrate;
mixing the first gas and the second gas in the mixing manifold to create a first gas mixture;
delivering the first gas mixture through one or more gas channels in the substrate and/or one or more outlets on the substrate to a semiconductor processing chamber downstream.

20. The method of claim 19, the method further comprising:
combining the first gas mixture with a tuning gas to create a second gas mixture;
delivering the second gas mixture to a plasma etching chamber; and
plasma etching a semiconductor substrate in the chamber.

21. The method of claim 19, wherein the first, second, third and fourth gas supply components are selected from a group comprising: an on/off gas valve, a mass flow controller (MFC), a vacuum coupling radiation (VCR) fitting, a manual gas valve, a gas pressure regulator, a gas filter, a purge gas component, a gas flow restrictor, and a pressure transducer.

22. The method of claim 19, wherein the gases are selected from the group comprising: a deposition gas, an etch gas, a tuning gas and a purge gas.

23. The method of claim 19, wherein the gas inlets include at least eight gas inlets arranged along one side of the laminate, each of the gas inlets in fluid communication with a mixing manifold in the laminate, via a gas flow path extending through gas channels and openings in the laminate, the method comprising opening a shutoff valve along the gas flow path such that a process gas travels through the gas flow path and passes through a mass flow controller and gas pressure regulator along the gas flow path.
